(19) United States
(12) Patent Application Publication
(10) Pub. No.: US 2012/0145447 A1
(43) Pub. Date: Jun. 14, 2012

(54) Via structure, method for forming the via structure, and circuit board with the via structure and method for manufacturing the circuit board

(75) Inventors: Bonghie Jung, Cheongju-si (KR); Minjung Cho, Suwon-si (KR); Kwangseop Youm, Cheongju-si (KR); Younghwan Shin, Daejeon-si (KR); Kyoungro Yoon, Daejeon-si (KR)

(73) Assignee: SAMSUNG ELECTRO-MECHANICS CO., LTD., Suwon (KR)

(21) Appl. No.: 13/064,689

(22) Filed: Apr. 8, 2011

(30) Foreign Application Priority Data
Dec. 8, 2010 (KR) 10-2010-0124636
Dec. 8, 2010 (KR) 10-2010-0124637

(51) Int. Cl. H05K 1/11; H05K 3/10

(52) U.S. Cl. 174/264; 29/852

(57) ABSTRACT

Disclosed herein is a via structure with a conductive via. There is provided a via structure, including: a substrate laminate having a multilayer structure and a via hole penetrating through the multilayer structure; a first circuit pattern formed on one surface of the substrate laminate; a second circuit pattern formed on the other surface of the substrate laminate; and a conductive via formed in the via hole and having one end connected to the first circuit pattern and the other end connected to the second circuit pattern, wherein the multilayer structure includes resin layers having different etching rates using an alkaline solution.

### CROSS REFERENCE(S) TO RELATED APPLICATIONS

This application claims the benefit under 35 U.S.C. Section [120, 119, 119(e)] of Korean Patent Application Serial No. 10-2010-0124636, 10-2010-0124637, entitled “Via Structure, Method For Forming The Via Structure, And Circuit Board With The Via Structure And Method For Manufacturing The Circuit Board” filed on Dec. 8, 2010, which is hereby incorporated by reference in its entirety into this application.

### BACKGROUND OF THE INVENTION

1. Technical Field

The present invention relates to a via structure, a method for forming the via structure, a circuit board with the via structure, and a method for manufacturing the circuit board, and more particularly, to a via structure with conductive vias capable of implementing thinness and fine-pitch, a method for forming the via structure, a circuit board with the via structure, and a method for manufacturing the circuit board.

2. Description of the Related Art

A process of manufacturing a build-up printed circuit board widely used for a semiconductor packaging includes a process of manufacturing a substrate laminate by stacking and firing a plurality of insulating films and performs a process of forming circuit patterns and conductive vias on the substrate laminate during a process of manufacturing the substrate laminate. In this case, the conductive vias are generally formed by forming the via hole on the substrate laminate by performing a laser machining process on the substrate laminate and then, filling a plating layer in the via hole.

However, as described above, in the case where the via hole is formed on the substrate laminate by a laser machining process, when considering the characteristics of the laser machining process, a via hole having a narrow width toward the inside of the substrate laminate are formed. Therefore, the conductive via formed in the via hole also has a shape having a narrow width toward the inside of the substrate laminate. In this case, the electrical resistance of the conductive via is increased, such that the electrical characteristics of the circuit board are degraded.

In addition, it is difficult to permeate a plating solution into the inside of the via hole having the above-mentioned structure with a relatively narrow width, such that the efficiency of forming the conductive via is degraded. In addition, when designing the printed circuit board, the two-dimensional occupying area of the conductive via is a portion having a relatively wider width of the conductive via. Therefore, as described above, the conductive vias having different upper and lower widths are restricting the design of the package substrate that requires thinness and a fine-pitch.

### SUMMARY OF THE INVENTION

An object of the present invention is to provide a via structure capable of implementing a thinness and fine-pitch of a circuit board and a method for forming the via structure.

Another object of the present invention is to provide a via structure including conductive vias of which the upper and lower widths are approximately the same and a method for forming the via structure.

Another object of the present invention is to provide a circuit board capable of implementing thinness and fine-pitch and a method for forming the circuit board.

Another object of the present invention is to provide a circuit board including conductive vias of which the upper and lower widths are approximately the same and a method for manufacturing the circuit board.

According to an exemplary embodiment of the present invention, there is provided a via structure, including: a substrate laminate having a multilayer structure and a via hole penetrating through the multilayer structure; a first circuit pattern formed on one surface of the substrate laminate; a second circuit pattern formed on the other surface of the substrate laminate; and a conductive via formed in the via hole and having one end connected to the first circuit pattern and the other end connected to the second circuit pattern, wherein the multilayer structure may include resin layers having different etching rates for an alkaline solution.

The resin layers may be made of a polymer resin composition having a resin and a filler, each of the resin layers may be provided to have a different content of the filler for the resin, and the resin layers may be disposed in sequence where the content of the filler for the resin is high toward a thickness direction of an insulator.

The resin layer having a relatively faster etching rate using the alkaline solution among the resin layers may have a higher content of the epoxy resin than a bismaleimide triazine resin as compared with the resin layer having the slower etching rate using the alkaline solution.

The conductive via may be formed so that a ratio of the width at the resin layer having the relatively faster etching rate using the alkaline solution among the resin layers and the width at the resin layer having the relatively slow etching rate using the alkaline solution satisfies 1:0.8 to 1:1.2.

According to another exemplary embodiment of the present invention, there is provided a method for manufacturing a via structure, including: manufacturing an insulator having a multilayer structure; forming a via hole penetrating through the multilayer structure; forming a first circuit pattern on one surface of the insulator; forming a second circuit pattern on the other surface of the insulator; forming a conductive via having one end connected to the first circuit pattern and the other end connected to the second circuit pattern in the via hole; and forming resin layers having different etching rates for an alkaline solution forming the insulator.

Each of the resin layers may be made of a polymer resin composition having a resin and a filler, and the forming the resin layers may include stacking the resin layers so that the content of the filler for the resin is relatively higher toward the thickness direction of the insulator.

The forming the resin layers may include stacking the resin layers so that the content of an epoxy resin is relatively higher than that of a bismaleimide triazine resin toward the thickness direction of the insulator.

The forming the via hole may include: forming a preliminary via hole having a narrower width at the other side of the insulator than that at one side of the insulator by irradiating a laser beam to one side of the insulator; and performing a desmear process on the insulator in order to expand a width at the other side of the insulator of the preliminary via hole.

The performing the desmear process may include expanding the width at the resin layer having a relatively faster etching rate using the alkaline solution so that a ratio of the width at the resin layer with the relatively faster etching rate using the alkaline solution among the resin layers and the width at the resin layer with the relatively slower etching rate using the alkaline solution satisfies 1:0.8 to 1:1.2.

According to another exemplary embodiment of the present invention, there is provided a circuit board, including: a base substrate having inner circuit patterns; an insulating layer covering the base substrate; a via hole penetrating through the base substrate and the insulating layer so that the inner circuit pattern is exposed; and a conductive via included in the via hole, wherein the base substrate includes a core layer made of a resin material, and the core layer includes a polymer resin layer made of a material having a faster etching rate using an alkaline chemical liquid, as compared with the insulating layer.

The core layer and the insulating layer may be made of a polymer resin composition having a resin and a filler, and the core layer may have a relatively higher content of the filler for the resin, as compared with the insulating layer.

The core layer may be formed so that the content ratio of the filler for the resin is 0.8 to 1.5.

The core layer and the insulating layer may be made of a complex resin composition having an epoxy resin and a bismaleimide triazine resin, and the core layer may have a higher content of the epoxy resin, as compared with the insulating layer.

The core layer may be made of the epoxy resin, and the insulating layer may be made of the bismaleimide triazine resin.

The conductive via may be formed so that a ratio of a width at the insulating layer and a width at the base substrate satisfies 1:0.8 to 1:1.2.

The inner circuit patterns may be formed on both surfaces of the base substrate, the circuit board may further include an outer circuit pattern covering the insulating layer, and one end of the conductive via may be connected to the inner circuit pattern formed on one surface of the base substrate and the other end thereof may be connected to the outer circuit pattern formed on the insulating layer covering the other surface of the base substrate.

The base substrate and the insulating layer may form a substrate laminate, the via hole may be formed by performing a laser machining process on the substrate laminate, and the conductive via may be a plating layer filling the via hole.

According to another exemplary embodiment of the present invention, there is provided a method for manufacturing a circuit board, including: preparing a base substrate having an inner circuit pattern; manufacturing a substrate laminate by forming an insulating layer covering the base substrate; forming a via hole exposing the inner circuit pattern on the substrate laminate; and forming a conductive via in the via hole, wherein the forming the insulating layer includes forming a polymer resin layer made of a resin material having a slow etching rate using an alkaline chemical liquid on the base substrate, as compared with the base substrate.

The forming the via hole may include: forming a preliminary via hole having a narrower width at the base substrate than a width at the insulating layer by performing a laser machining process on the substrate laminate; and expanding the width at the base substrate of the preliminary via hole so that a ratio of the width at the insulating layer and the width at the base substrate satisfies 1:0.8 to 1:1.2.

The expanding the width at the base substrate of the preliminary via hole may include performing a desmear process having a faster etching rate for the base substrate than for the insulating layer on the substrate laminate.

The expanding the width at the base substrate of the preliminary via hole may include supplying an alkaline chemical liquid having etch selectivity for the base substrate to the substrate laminate.

The preparing the base substrate may include preparing a copper clad laminate having a core layer made of a resin material, and the forming the insulating layer may include forming a polymer resin layer made of a slower etching rate by an alkaline chemical liquid on the copper clad laminate, as compared with the core layer.

The forming the insulating layer may include laminating a polymer sheet having a lower content of a filler than that of a resin as compared with the core layer on the copper clad laminate.

The core layer may be formed so that the content ratio of the filler for the resin is 0.8 to 1.5.

The forming the polymer resin layer may include laminating a polymer sheet having a relatively higher content of a bismaleimide triazine resin, as compared with the copper clad laminate.

According to another exemplary embodiment of the present invention, there is provided a circuit board, including: a base substrate having inner circuit patterns; an insulating layer covering the base substrate and having a multilayer structure; a via hole penetrating through the insulating layer so that the inner circuit pattern is exposed; and a conductive via provided in the via hole, wherein the multilayer structure is made of a resin material having a low decomposition rate using an alkaline chemical liquid toward the base substrate.

The multilayer structure may include: an inner layer covering the base substrate; and an outer layer covering the inner layer, wherein the inner layer may include a prepreg layer made of a resin material and the outer layer may include a prepreg layer made of a resin material having a low decomposition rate using an alkaline chemical liquid, as compared with the inner layer.

The multilayer structure may be made of a polymer resin composition including a resin and a filler, and the multilayer structure may include: an inner layer covering the base substrate; and an outer layer covering the inner layer, wherein the inner layer has a higher content of the filler for the resin, as compared with the outer layer.

The inner layer may be formed so that the content ratio of the filler for the resin is 0.8 to 1.5.

The multilayer structure may include: an inner layer covering the base substrate; and an outer layer covering the inner layer, wherein the conductive via may be formed so that a ratio of the width at the outer layer and the width of the inner layer satisfies 1:0.8 to 1:1.2.

The circuit board may further include an outer circuit pattern covering the insulating layer, wherein one end of the conductive via is connected to the inner circuit pattern and the other end thereof is connected to the outer circuit pattern.

The base substrate and the insulating layer may form a substrate laminate, the via hole may be formed by performing a laser machining process on the substrate laminate, and the conductive via may a plating layer filling the via hole.

According to the exemplary embodiment of the present invention, there is provided a method for manufacturing a circuit board, including: preparing a base substrate having inner circuit patterns; manufacturing a substrate laminate by forming an insulating layer on the base substrate; forming a via hole exposing the inner circuit pattern on the substrate laminate; and forming a conductive via having a shape corresponding to the via hole in the via hole, wherein the forming the insulating layer may include: forming an inner layer adjacent to the base substrate; and forming an outer layer made of a resin material having a low decomposition rate using an alkaline chemical liquid on the inner layer, as compared with the inner layer.

The forming the via hole may include: forming a preliminary via hole having a narrower width at the inner layer than a width at the outer layer by performing a laser machining process on the substrate laminate; and expanding the width at the inner layer of the preliminary via hole so that a ratio of the width at the outer layer and the width at the inner layer satisfies 1:0.8 to 1:1.2.

The expanding the width at the inner layer of the preliminary via hole may include performing a desmear process having a faster etching rate for the inner layer than for the outer layer on the substrate laminate.

The expanding the width at the inner layer of the preliminary via hole may include supplying an alkaline chemical liquid having etch selectivity for the inner layer to the substrate laminate.

The forming the insulating layer may include laminating a polymer sheet including the inner layer and the outer layer on the base substrate.

The forming the outer layer may include laminating a polymer sheet having a lower content of a filler for a resin as compared to the inner layer on the inner layer.

The inner layer may be formed so that the content ratio of the filler for the resin is 0.8 to 1.5.

The forming the outer layer may include laminating a polymer sheet having a relatively higher content of a bismaleimide triazine resin, as compared with the copper clad laminate.

### BRIEF DESCRIPTION OF THE DRAWINGS

FIG. 1 is a diagram showing a circuit board according to an exemplary embodiment of the present invention;

FIG. 2 is a flow chart showing a method for manufacturing a circuit board according to the exemplary embodiment of the present invention;

FIGS. 3A to 3E are diagrams for explaining a method for manufacturing a circuit board according to the exemplary embodiment of the present invention;

FIG. 4 is a diagram showing a circuit board according to another exemplary embodiment of the present invention;

FIG. 5 is a flow chart showing a method for manufacturing a circuit board according to another exemplary embodiment of the present invention; and

FIGS. 6A to 6E are diagrams for explaining a method for manufacturing a circuit board according to another exemplary embodiment of the present invention.

### DESCRIPTION OF THE PREFERRED EMBODIMENTS

Advantages and characteristics of the present invention, and a method for achieving them will be apparent with reference to embodiments described below in addition to the accompanying drawings. However, the present invention is not limited to the embodiments disclosed below, but may be implemented in various forms. The embodiments may be provided to completely disclose the present invention and allow those skilled in the art to completely know the scope of the present invention. Throughout the specification, like elements refer to like reference numerals.

Terms used in the specification are used to explain the embodiments and not to limit the present invention. In the specification, a singular type may also be used as a plural type unless stated specifically. “Comprises” and/or “comprising” used the specification mentioned constituent members, steps, operations and/or elements do not exclude the existence or addition of one or more other components, steps, operations and/or elements.

Further, the exemplary embodiments described in the specification will be described with reference to cross-sectional views and/or plan views that are ideal exemplification figures. In the drawings, the thickness of layers and regions may be exaggerated for efficient description of technical contents and consequently, exemplified forms may be changed by manufacturing technologies and/or tolerances. Therefore, the exemplary embodiments of the present invention are not limited to specific forms but may include the change in forms generated according to the manufacturing processes. For example, an etching region vertically shown may be rounded or may have a predetermined curvature. Therefore, the regions shown in the drawings have schematic attributes and the shapes shown in the drawings show specific shapes of device regions by way of example only but are not limited to the scope of the present invention.

Hereinafter, a via structure, a method for forming the via structure, a circuit board with the via structure, and a method for manufacturing the circuit board according to the exemplary embodiment of the present invention will be described in detail with reference to the accompanying drawings.

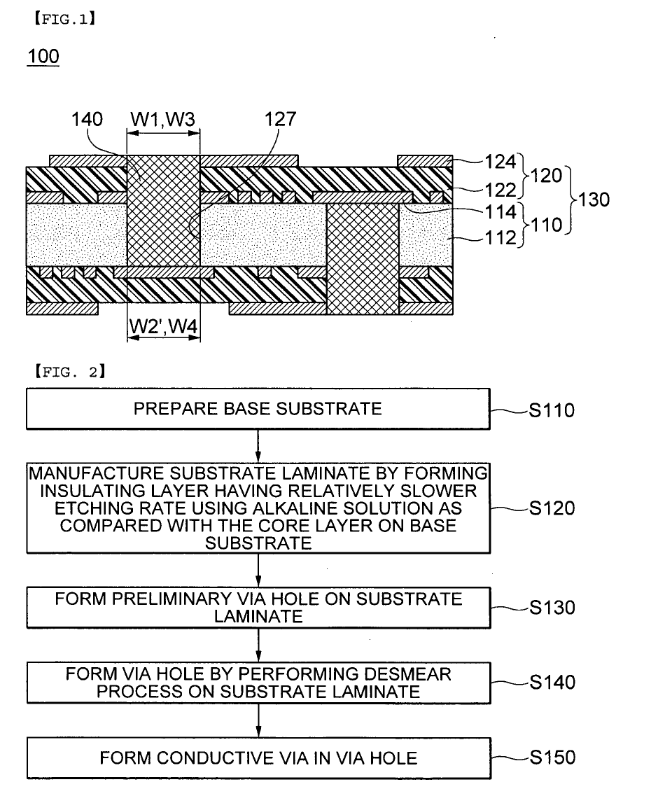

FIG. 1 is a diagram showing a circuit board according to an exemplary embodiment of the present invention. Referring to FIG. 1, a circuit board 100 according to an exemplary embodiment of the present invention may include a build-up printed circuit board (build-up PCB). The circuit board 100 may include a structure (hereinafter, via structure) having a predetermined conductive via. The via structure may include a substrate laminate 130 where a plurality of insulating films are stacked and a conductive via 140 included in the substrate laminate 130.

The substrate laminate 130 may have a multilayer structure where a plurality of insulating films are stacked. The substrate laminate 130 may include a base substrate 110 and an insulating layer 120 formed on both surfaces of the base substrate 110. The base substrate 110 may be a layer disposed at the center of the multilayer structure. The base substrate 110 may include a core layer 112 and an inner circuit pattern 114 formed in the core layer 112. The base substrate 110 having the above-mentioned structure may include a thin plate called a copper clad laminate (CCL).

The insulating layer 120 may include a prepreg layer 122 covering the core layer 112. The surface of the prepreg layer 122 may be provided with outer circuit patterns 124.

In this configuration, the substrate laminate 130 may have a via hole 127 penetrating through the core layer 112 and the prepreg layer 122. The via hole 127 may be configured so that a ratio of a width (hereinafter, referred to as an outer side width: W1) at the prepreg layer 122 to a width (hereinafter, referred to as an inner side width: W2′) at the core layer 112 is approximately 1:0.8 to 1:1.2. Preferably, the outer side width W1 and the inner side width W2′ can be controlled to be approximately the same. Therefore, the via hole 127 may have the column shape having approximately the same upper width and lower width.

Meanwhile, the core layer 112 and the prepreg layer 122 may be made of different materials. For example, the core layer 112 may be made of a polymer resin rapidly decomposed by an alkaline solution, as compared with the prepreg layer 122. The alkaline solution may be a chemical liquid used later to perform a desmear process on the substrate laminate 130. Therefore, the core layer 112 may be rapidly decomposed by the alkaline solution and may be etched at a fast rate using the alkaline solution, as compared with the prepreg layer 122.

As described above, a technology for generating the difference in the etching rate of the core layer 112 and the prepreg layer 122 using the alkaline solution may be diverse. For example, the core layer 112 and the prepreg layer 122 may be made of a complex resin composition including a resin and a filler. In this case, in order to control the content of the filler, it is possible to control the etching rate for the alkaline solution. For example, as compared with an epoxy resin, it was confirmed that the decomposition rate for the alkaline solution is increased with the increase in the content of the filler. Therefore, unlike the prepreg layer 122, the content of the filler is relatively increased in the core layer 112, such that the decomposition rate of the core layer 112 for the alkaline solution may be increased, as compared with the prepreg layer 122. In this case, as the filler, a silica may be used. Alternatively, as the filler, a glass composition may be used.

However, when the content ratio of the filler for the epoxy resin exceeds approximately 1.5, the shot frequency is increased at the time of irradiating the carbon dioxide laser beam, thereby making it possible to degrade the machining efficiency. On the other hand, when the content ratio of the filler for the epoxy resin is below approximately 0.8, the value of thermal expansion coefficient (CTE) is relatively increased, such that the bending characteristics of the manufactured substrate may be degraded. Therefore, the core layer 112 has a relatively higher content of the filler as compared with the prepreg layer 122 and the content of the filler may be controlled to meet the range of approximately 0.8 to 1.5 as compared with the content of the resin.

As another example, the core layer 112 and the prepreg layer 122 are made of different resin materials, such that the alkali decomposition rate of the core layer 112 may be increased, as compared with the prepreg layer 122. In more detail, as a representative resin, there are an epoxy resin and bismaleimide triazine resin. The epoxy resin has a smaller molecular weight and a more compact texture than that of the bismaleimide triazine resin such that it can be relatively rapidly etched using the alkaline solution during the desmear process. Therefore, the decomposition rate of the core layer 112 may be increased as compared with the prepreg layer 122 by making the core layer 112 be composed of the epoxy resin material and the prepreg layer 122 be composed of the bismaleimide triazine resin. Alternatively, the core layer 112 and the prepreg layer 122 are made of a complex resin composition having the epoxy resin and the bismaleimide triazine resin, but the core layer 112 is controlled to have a relatively higher content of epoxy resin and the prepreg layer 122 is controlled to have a relatively higher content of bismaleimide triazine resin, such that the decomposition rate of the core layer 112 can be relatively increased as compared with the prepreg layer 122.

The conductive via 140 may be included in the via hole 127 within the substrate laminate 130. For example, the conductive via 140 may vertically penetrate through the substrate laminate 130. In addition, one end of the conductive via 140 may be connected to the inner circuit pattern 114 and the other end thereof may be connected to the outer circuit pattern 124. In more detail, one end of the conductive via 140 may be connected to the inner circuit pattern 114 formed on one surface of the base substrate 110 and the other end thereof may be connected to the outer circuit pattern 124 formed on the insulating layer 120 covering the other surface of the base substrate 110. Therefore, the conductive via 140 may electrically connect the inner circuit pattern 114 to the outer circuit pattern 124.

In addition, the conductive via 140 may be provided to have the shape corresponding to the via hole 127 within the via hole 127. Therefore, the conductive via 140 may be configured so that the outer side width (hereinafter, referred to as an upper width: W3) at the substrate laminate 130 to the inner side width (hereinafter, referred to as a lower width: W4) at the substrate laminate 130 may satisfy approximately 1:0.8 to 1:1.2. Preferably, the upper width W3 and the lower width W4 can be controlled to be approximately the same. In addition, the conductive via 140 may have a column shape having a transverse section having an island shape. The conductive via 140 having the above-mentioned structure may have a relatively smaller electrical resistance, as compared with the conductive via of which the upper and lower widths are different. That is, the conductive via 140 has approximately the same upper width W3 and lower width W4, thereby making it possible to further reduce the electrical resistance thereof as compared with the structure where any one of the upper width W3 and the lower width W4 is narrow.

In addition, the conductive via 140 has approximately the same upper and lower widths W3 and W4, such that the two-dimensional occupying area of the substrate laminate 130 may be smaller than the conductive via of which the upper and lower widths are different under the condition of having the same electrical resistance. In more detail, the conductive via of which the upper and lower widths are different has a structure where the electrical resistance is relatively higher than that of the conductive via 140. Therefore, at least any one of the upper width and the lower width should be relatively wider than the upper width W3 and the lower width W4 of the conductive via 140 so that the electrical resistance value of the conductive via of which the upper and lower widths are different is the same as that of the conductive via 140. In this case, the conductive via of which the upper and lower widths are different has the two-dimensionally increased occupying area. Therefore, the conductive via 140 having the above-mentioned structure can reduce the occupying area of the circuit board 100 as compared with the conductive via of which the upper and lower widths are different.

As described above, the via structure and the circuit board 100 having the via structure according to the exemplary embodiment of the present invention may include the substrate laminate 130 where the base substrate 110 and the insulating layer 120 are stacked and may include the conductive via 140 penetrating through the base substrate 110 and the insulating layer 120 and having the approximately same upper width W3 and lower width W4. Therefore, the via structure and the circuit board with the via structure according to the exemplary embodiment of the present invention have the conductive via of which the upper and lower widths are approximately the same to reduce the electrical resistance thereof, such that they can have a structure with improved electrical characteristics.

In addition, the via structure and the circuit board 100 with the via structure according to the exemplary embodiment of the present invention may include the conductive via 140 of which the upper and lower widths are approximately the same. In this case, the conductive via 140 can reduce the occupying area of the substrate laminate 130, as compared with the conductive via of which the upper and lower widths are different under the condition having the same electrical resistance. Therefore, the via structure and the circuit board with the via structure according to the exemplary embodiment of the present invention includes the conductive via of which the upper and lower widths are approximately the same to relatively reduce the occupying area thereof, thereby making it possible to implement the structure where thinness and fine-pitch of the circuit board can be achieved.

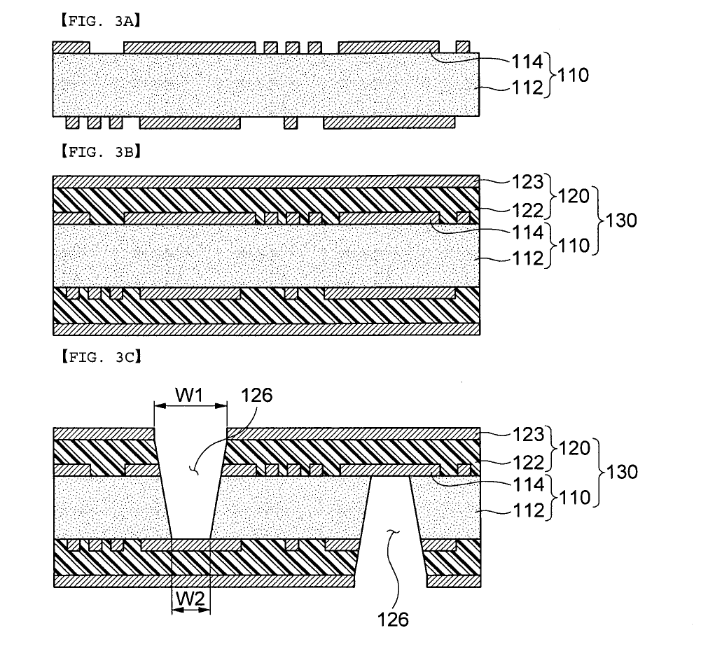

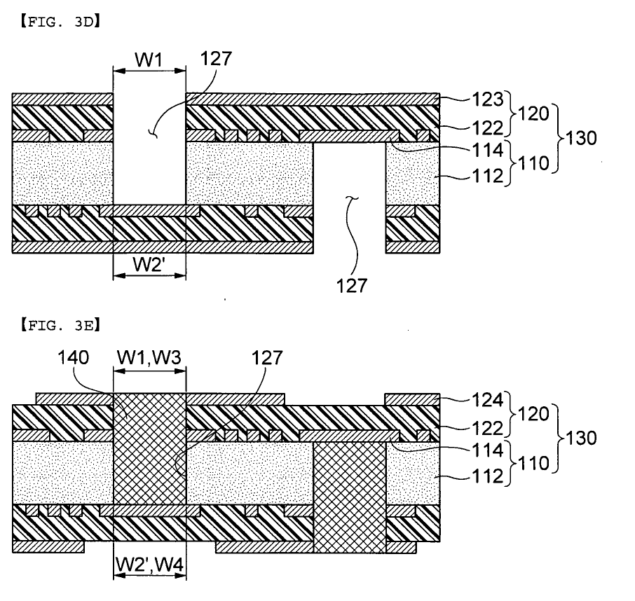

FIG. 2 is a flow chart showing a method for manufacturing a circuit board according to the exemplary embodiment of the present invention and FIGS. 3A to 3E are diagrams for explaining a method for manufacturing a circuit board according to the exemplary embodiment of the present invention.

Referring to FIGS. 2 and 3A, the base substrate 110 may be prepared (S110). As an example, the preparing of the base substrate 110 may include preparing the copper clad laminate (CCL). That is, the preparing of the base substrate 110 may include preparing the core layer 112 covered with a predetermined metal layer. The core layer 112 may be a polymer sheet having a resin-based material and the metal layer may be a copper layer. The inner circuit pattern 114 may be formed on the core layer 112 by selectively removing a portion of the metal layer. Therefore, the base substrate 110 having the core layer 112 and the inner circuit patterns 114 formed on both surfaces of the core layer 112 may be prepared.

Referring to FIGS. 2 and 3B, the insulating layers 120 having a relatively slower etching rate using the alkaline solution as compared with that of the core layer 112 are formed on both surfaces of the base substrate 110, thereby making it possible to form the substrate laminate 130 (S120). For example, the prepreg layers 122 may be formed on both surfaces of the core layer 112. The forming of the prepreg layers 122 may be made on both surfaces of the core layer 112 by laminating the polymer sheet having the resin-based material.

In addition, the method for manufacturing a circuit board may include forming the metal layer 123 on the surface of the prepreg layer 122. In this case, the metal layer 123 may be a seed layer for forming the outer circuit pattern by the plating process later. Alternatively, the metal layer 123 may be a copper layer for forming the outer circuit patterns by the patterning process later.

In this case, the core layer 112 may be made of a material having a high decomposition rate using the alkaline solution, as compared with the prepreg layer 122. As an example, the core layer 112 may be made of a material having higher content of the filler for the resin, as compared with the prepreg layer 122. In this case, the core layer 112 may be controlled so that the content ratio of the filler for the resin is 0.8 to 1.5. As another example, the core layer 112 may be made of a material having a relatively higher content of the epoxy resin including the bismaleimide triazine resin, as compared with the prepreg layer 122. As another example, the core layer 112 may be made of the epoxy resin and the prepreg layer 122 may be made of the bismaleimide triazine resin.

Referring to FIGS. 2 and 3C, a preliminary via hole 126 may be formed on the substrate laminate 130 (S130). The forming of the preliminary via hole 126 may form a groove exposing the inner circuit pattern 114 to the substrate laminate 130 by using the laser machining process.

In this case, the preliminary via hole 126 may have the shape where the outer side width and the inner side width are different from each other. In more detail, the preliminary via hole 126 is formed by using the laser machining process, such that it may have a shape having a narrow width toward the inner side of the substrate laminate 130. Therefore, the preliminary via hole 126 may have a column shape having a narrower width (hereinafter, referred to as an inner side width: W2) at the inner side portion, as compared with a width (hereinafter, referred to as an outer side width: W1) at the outer side portion of the substrate laminate 130.

Referring to FIGS. 2 and 3D, the via hole 127 may be formed by performing the desmear process on the substrate laminate 130 (S140). For example, a chemical liquid used for the desmear process may be supplied to the substrate laminate 130. The chemical liquid may be a solution having a higher etching rate for the base substrate 110 than the insulating layer 120. In this case, the chemical liquid supplied to the inside of the preliminary via hole 126 may etch the base substrate 110 at a faster rate than the insulating layer 120. As the chemical liquid, a solution having higher etching selectivity for the base substrate 110 than that of the insulating layer 120 may be used so that the etching is mainly performed for the base substrate 110 rather than for the insulating layer 120. As the chemical liquid, a chemical having strong alkalinity capable of decomposing the polymer resin may be used.

By the above-mentioned desmear process, the inner side width W2 of the preliminary via hole 126 is widened, such that the it may be extended to the inner side width W2′ having the approximately same width as the outer side width W1. Therefore, the substrate laminate 130 may be formed with the via hole 127 having a column shape where the ratio of the inner side width W2′ to the outer side width W1 satisfies 1:0.8 to 1:1.2.

Referring to FIGS. 2 and 3E, the conductive via 140 may be formed in the via hole 127 (S150). The forming of the conductive via 140 may include forming a resist pattern exposing the via hole 127 on the substrate laminate 130 and performing a copper plating process on the substrate laminate 130 by using the resist pattern as a plating preventing layer. As the copper plating process, an electroplating process or an electroless plating process may be used. Therefore, the via hole 127 may be filled with a copper plating layer, such that the conductive via 140 may be formed therein. In this case, the via hole 127 has approximately the same outer side width W1 and inner side width W2′, such that the plating solution used during the copper plating process may be effectively permeated to the inner side portion of the via hole 127, thereby making it possible to increase the efficiency of forming the conductive via 140.

In this case, the via hole 127 has a column shape where the outer side width W1 and the inner side width W2′ are approximately the same, such that the conductive via 140 formed in the via hole 127 may have a column shape in the upper and lower widths that are approximately the same. Therefore, the via hole 127 may be formed with the conductive via 140 having the structure where the upper width W3 and the lower width W4 are approximately the same.

Meanwhile, the outer circuit pattern 124 may be formed on the substrate laminate 130. The forming of the outer circuit pattern 124 may be made by forming the plating layer of the substrate laminate 130 by using the metal layer 123 (FIG. 3D) formed on the insulating layer 120 as the seed layer during the process of performing the copper plating process. Alternatively, the forming of the outer circuit pattern 124 may be formed by patterning the metal layer 123. Through the above-mentioned processes, the via structure with the conductive via 140 of which the upper and lower widths are approximately the same and the circuit board may be manufactured.

The method for manufacturing a via structure and a circuit board with the via structure according to the exemplary embodiment of the present invention manufactures the substrate laminate 130 by forming the insulating layer 120 on the base substrate 110 and forms on the substrate laminate 130 the via hole 127 having approximately the same outer side width W1 and inner side width W2′ penetrating through the base substrate 110 and the insulating layer 120, and then, forms the conductive via 140 in the via hole 127. Therefore, the method for manufacturing a via structure and a circuit board according to the exemplary embodiment of the present invention have the conductive via of which the upper and lower widths are approximately the same to reduce the electrical resistance thereof, such that the circuit board having the structure with improved electrical characteristics can be manufactured.

The method for manufacturing the via structure and the circuit board with the via structure according to the exemplary embodiment of the present invention manufactures the substrate laminate 130 by forming the insulating layer 120 on the base substrate 110 and forms the conductive via 140 where the width at the base substrate 110 and the width at the insulating layer 120 are approximately the same while penetrating through the base substrate 110 and the insulating layer 120. In this case, the conductive via 140 can reduce the occupying area of the substrate laminate 130, as compared with the conductive via of which the upper and lower widths are different under the condition of having the same electrical resistance. Therefore, the method for manufacturing a via structure and a circuit board with the via structure according to the exemplary embodiment of the present invention may form the conductive via of which the upper and lower widths are approximately the same to relatively reduce the occupying area, such that a thin and fine-pitch circuit board can be manufactured.

In addition, the method for manufacturing a via structure and a circuit board with the via structure according to the exemplary embodiment of the present invention may form the via hole 127 having the same shape where the outer side width W1 and the inner side width W2′ are approximately the same and then, form the conductive via 140 in the via hole 127 by the plating process. Therefore, the method for manufacturing a via structure and a circuit board with the via structure according to the exemplary embodiment of the present invention can form the via hole to facilitate the permeation of the plating solution, as compared with the via hole having a narrow width toward the base substrate, thereby making it possible to improve the efficiency of forming the conductive via.

Hereinafter, the circuit board and the method for manufacturing the circuit board according to another embodiment of the present invention will be described in detail. In this case, the overlapping contents of the circuit board and the method for manufacturing the circuit board according to the embodiment of the present invention as described above will be omitted or simplified.

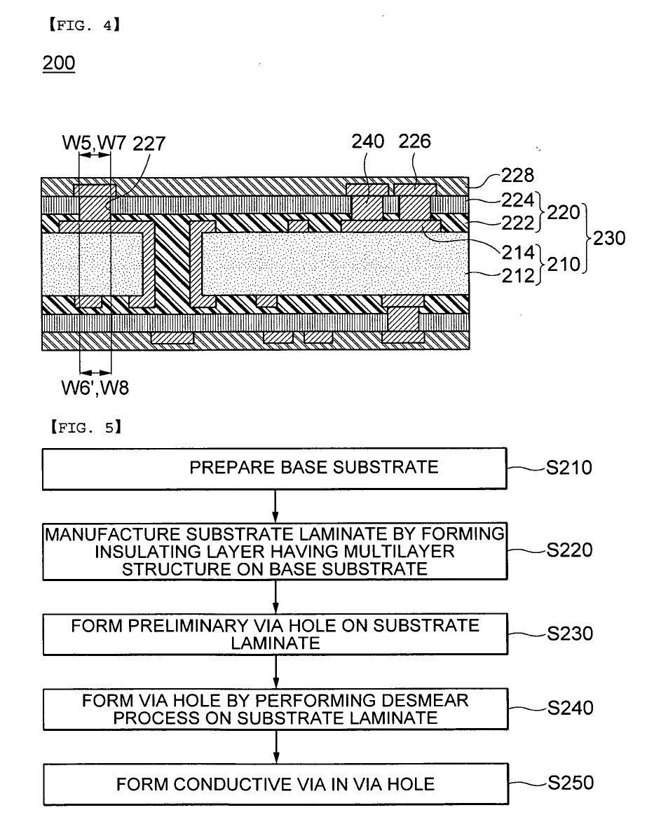

FIG. 4 is a diagram showing a circuit board according to another exemplary embodiment of the present invention. Referring to FIG. 4, a circuit board 200 according to another exemplary embodiment of the present invention may include a structure (hereinafter, referred to as the ‘via structure’) having a predetermined conductive via. The via structure may include a substrate laminate 230 where a plurality of insulating films are stacked and a conductive via 240 is included in the substrate laminate 230.

The substrate laminate 230 may include a multilayer structure including a base substrate 210 and insulating layers 220 formed at both surfaces of the base substrate 210. The base substrate 210 may include a core layer 212 and an inner circuit pattern 214 formed in the core layer 212. The base substrate 210 having the above-mentioned structure may include a thin plate called a copper clad laminate (CCL).

The insulating layer 220 may cover both surfaces of the core layer 212. The insulating layer 220 may have a multilayer structure having a plurality of insulating layers. As an example, the insulating layer 220 may include an inner layer 222 relatively adjacent to the core layer 212 and an outer layer 224 disposed at the outer side of the substrate laminate 230, as compared with the inner layer 222. The inner layer 222 may cover the core layer 212 and the outer layer 224 may cover the inner layer 222. The surface of the outer layer 224 may be provided with the outer circuit pattern 226. The surface of the outer layer 224 may be provided with the resist pattern 228. The resist pattern 228 may have an opening (not shown) selectively exposing a portion of the outer circuit pattern 226.

In this case, the inner layer 222 and the outer layer 224 may be made of different materials. For example, the inner layer 222 may be made of a prepreg material having a rapid decomposition rate using an alkaline solution, as compared with the outer layer 224. The alkaline solution may be a chemical liquid used later to perform a desmear process on the substrate laminate 230. Therefore, the inner layer 222 has a high decomposition rate using the alkaline solution as compared with the outer layer 224, such that it may be rapidly etched using the alkaline solution.

As described above, a technology for generating the difference in the etching rate of the inner layer 222 and the outer layer 224 using the alkaline solution may be diverse. As an example, the inner layer 222 and the outer layer 224 may be made of a complex resin composition including a resin and a filler. In this case, in order control to the content of the filler, the etching rate for the alkaline solution can be controlled. For example, unlike the outer layer 224, the content of the filler is relatively increased in the inner layer 222, such that the decomposition rate of the inner layer 222 using the alkaline solution may be increased, as compared with the outer layer 224. In this case, as the filler, at least any one of silica or glass composition may be used.

However, when the content ratio of the filler for the epoxy resin exceeds approximately 1.5, the shot frequency is increased at the time of irradiating the carbon dioxide laser beam, thereby making it possible to degrade the machining efficiency. On the other hand, when the content ratio of the filler for the epoxy resin is below approximately 0.8, the value of thermal expansion coefficient (CTE) is relatively increased, such that the bending characteristics of the manufactured substrate may be degraded. Therefore, the inner layer 222 has a relatively higher content of the filler as compared with the outer layer 224 and the content of the filler may be controlled to meet the range of approximately 0.8 to 1.5 as compared with the content of the resin.

As another example, the inner layer 222 and the outer layer 224 are made of different resin materials, such that the alkali decomposition rate of the inner layer 222 may be increased, as compared with the outer layer 224. For example, the decomposition rate of the inner layer 112 may be increased as compared with the outer layer 122 by composing the inner layer 222 of the epoxy resin material and composing the outer layer 224 of the bismaleimide triazine resin. Alternatively, the inner layer 22 is controlled to have a relatively higher content of epoxy resin and the outer layer 224 is controlled to have a relatively higher content of bismaleimide triazine resin, such that the decomposition rate of the inner layer 222 can be increased.

The exemplary embodiment of the present invention describes, by way of example, the case where the insulating layer 220 has a double layer composed of the inner layer 222 and the outer layer 224, but the insulating layer 2202 may have a multilayer structure composed of at least three layers. In this case, as the layer is adjacent to the core layer 212, the layers may be configured to increase the decomposition rate using the alkaline solution.

Meanwhile, the substrate laminate 230 may have the via hole 227 penetrating through the inner layer 222 and the outer layer 224. The via hole 227 may be controlled so that a ratio of a width (hereinafter, referred to as an outside width: W5) at the outer layer 224 to a width (hereinafter, an inner side width: W6′) of the inner layer 222 satisfies approximately 1:0.8 to 1:1.2. Preferably, the outer side width W5 and the inner side width W6′ can be controlled to have approximately the same width. Therefore, the via hole 227 may have the column shape having approximately the same upper width and lower width.

The conductive via 240 may be included in the via hole 227 within the substrate laminate 230. For example, the conductive via 240 may be formed to vertically penetrate through the insulating layer 220. In addition, one end of the conductive via 240 may be connected to the inner circuit pattern 214 and the other end thereof may be connected to the outer circuit pattern 226. Therefore, the conductive via 240 may electrically connect the inner circuit pattern 214 to the outer circuit pattern 226.

In addition, the conductive via 240 may be provided to have the shape corresponding to the via hole 227 within the via hole 227. Therefore, the conductive via 240 may have a structure in which the ratio of the width (hereinafter, referred to as an outside width: W7) at the outer layer 224 to the width (hereinafter, an inner side width: W8) of the inner layer 222 satisfies approximately 1:0.8 to 1:1.2. In addition, the conductive via 240 may have a column shape having a transverse section having an island shape. That is, the conductive via 240 has approximately the same upper width W7 and lower width W8, thereby making it possible to further reduce the electrical resistance thereof as compared with the structure where any one of the upper width W7 or the lower width W8 is narrow. In addition, the conductive via 240 has approximately the same upper and lower widths W7 and W8, such that the two-dimensional occupying area of the substrate laminate 230 may be smaller than the conductive via of which the upper and lower widths are different under the condition of having the same electrical resistance. Therefore, the conductive via 240 having the above-mentioned structure can reduce the occupying area of the circuit board 200 as compared with the conductive via of which the upper and lower widths are different.

As described above, the circuit board 200 according to another exemplary embodiment of the present invention may have the substrate laminate 230 covering the base substrate 210 and including the insulating layer 220 having the inner layer 222 and the outer layer 224 and the conductive via 240 provided to penetrate through the inner layer 222 and the outer layer 224 and having approximately the same upper width W7 and lower width W8. Therefore, the circuit board according to the exemplary embodiment of the present invention have the conductive via of which the upper and lower widths are approximately the same to reduce the electrical resistance thereof, such that they can have a structure with improved electrical characteristics.

In addition, the circuit board 200 according to another exemplary embodiment of the present invention is provided on the insulating layer 220 of the substrate laminate 230 and may include the conductive via 240 having the structure where the upper and lower widths are approximately the same. The conductive via 240 can reduce the occupying area of the substrate laminate 230, as compared with the conductive via of which the upper and lower widths are different under the condition having the same electrical resistance. Therefore, the circuit board according to the exemplary embodiment of the present invention includes the conductive vias of which the upper and lower widths are approximately the same to relatively reduce the occupying area of the conductive vias thereof, thereby making it possible to implement the structure where thinness and fine-pitch of the circuit board can be achieved.

Continuously, the method for manufacturing a circuit board according to another embodiment of the present invention will be described in detail. In this case, the overlapping contents of the circuit board 200 according to another exemplary embodiment of the present invention described with reference to FIG. 4 may be omitted or simplified.

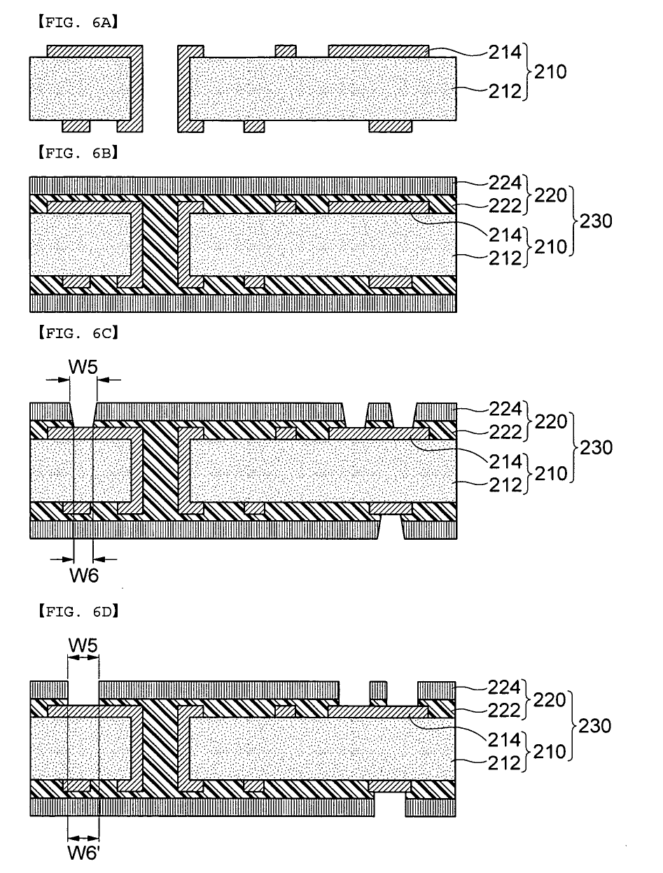

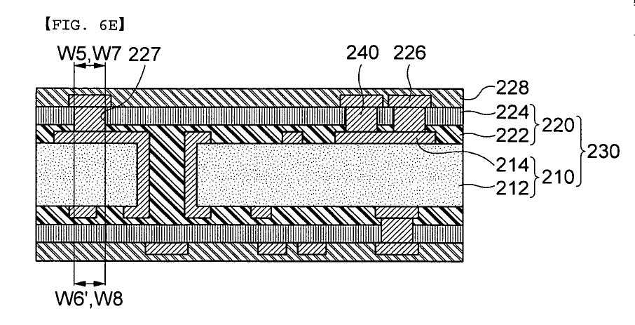

FIG. 5 is a flow chart showing a method for manufacturing a circuit board according to the exemplary embodiment of the present invention and FIGS. 6A to 6E are diagrams for explaining a method for manufacturing a circuit board according to another exemplary embodiment of the present invention.

Referring to FIGS. 5 and 6A, the base substrate 210 may be prepared (S210). As an example, the preparing of the base substrate 210 may include preparing the core layer 212 covering the predetermined metal layer and the forming of the inner circuit pattern 214 on the core layer 212 by selectively removing a portion of the metal layer. As the core layer 212, the copper clad laminate may be used. Therefore, the base substrate 210 having the core layer 212 and the inner circuit patterns 214 formed on both surfaces of the core layer 212 may be prepared.

Referring to FIGS. 5 and 6B, the substrate laminate 230 may be formed by forming the insulating layer 220 having the multilayer structure on the base substrate 210 (S220). For example, the forming of the insulating layer 220 may include forming the prepreg layer having the inner layer 222 and the outer layer 224 sequentially stacked on the core layer 212. As an example, the forming of the prepreg layer may be made by laminating the polymer sheet composed of the inner layer 222 and the outer layer 224 on both surfaces of the core layer 212. As another example, the forming of the prepreg layer may be made by sequentially laminating the polymer sheet for forming the inner layer 222 and the polymer sheet for forming the outer layer 224 on both surfaces of the core layer 212.

In this case, the inner layer 222 may be made of a material having the rapid decomposition rate for the alkaline solution, as compared with the outer layer 224. As an example, the inner layer 222 may be formed by laminating on the base substrate 210 the polymer sheet having higher content of the filler for the resin, as compared with the outer layer 224. In this case, the inner layer 222 may be controlled so that the content ratio of the filler for the resin is 0.8 to 1.5. As another example, the inner layer 222 may be formed by laminating on the base substrate 210 the polymer sheet having relatively higher content of the epoxy resin than the bismaleimide triazine resin, as compared with the outer layer 224. As another example, the inner layer 222 may be made of the epoxy resin and the outer layer 224 may be made of the bismaleimide triazine resin.

Referring to FIGS. 5 and 6C, the preliminary via hole 226 may be formed on the substrate laminate 230 (S230). The forming of the preliminary via hole 226 may include forming the groove exposing the inner circuit pattern 214 to the substrate laminate 230 by using the laser machining process.

In this case, the preliminary via hole 226 may have the shape where the outer side width and the inner side width are different from each other. In more detail, the preliminary via hole 226 is formed by using the laser machining process, such that it may have a shape having a narrow width toward the inner side of the substrate laminate 230. Therefore, the preliminary via hole 226 may have a column shape having a narrower width (hereinafter, referred to as a lower width: W6) at the inner layer 222, as compared with a width (hereinafter, referred to as an outer side width: W5) at the outer layer 224 of the insulating layer 220.

Referring to FIGS. 5 and 6D, the via hole 227 may be formed by performing the desmear process on the substrate laminate 230 (S240). For example, a chemical liquid for the desmear process may be supplied to the substrate laminate 230. The chemical liquid may be a solution having a faster etching rate for the inner layer 222, as compared with the outer layer 224 of the insulating layer 220. In this case, the chemical liquid supplied to the inside of the preliminary via hole 226 may etch the inner layer 222 at a faster rate than the outer layer 224. In this case, the chemical liquid having high etching selectivity for the base substrate 210 may be used so that the etching is mainly performed for the inner layer 222 rather than the outer layer 224. As the chemical liquid, a chemical having alkalinity capable of decomposing the polymer resin may be used.

By the above-mentioned desmear process, the inner side width W6 of the preliminary via hole 216 is widened, such that the it may be extended to the inner side width W6′ having the approximately same width as the outer side width W5. Therefore, the insulating layer 220 may be formed with the via hole 227 having a column shape so that the ratio of the outer side width W5 to the inner side width W6′ satisfies approximately 1:0.8 to 1:1.2.

Referring to FIGS. 5 and 6E, the conductive via 240 may be formed in the via hole 227 (S250). The forming of the conductive via 240 may include forming a resist pattern (not shown) exposing the via hole 227 on the substrate laminate 230 and performing the copper plating process on the substrate laminate 230 by using the resist pattern as the plating preventing layer. Therefore, the via hole 227 may be filled with a copper plating layer, such that the conductive via 240 may be formed therein. In this case, the via hole 227 has approximately the same outer side width W5 and inner side width W6′, such that the plating solution used during the copper plating process may be effectively permeated to the inner side portion of the via hole 227, thereby making it possible to increase the efficiency of forming the conductive via 240.

In this case, the via hole 227 has a column shape where the outer side width W5 and the inner side width W6′ are approximately the same, such that the conductive via 240 formed in the via hole 227 may have a column shape in the upper and lower widths are approximately the same. Therefore, the via hole 227 may be formed with the conductive via 240 so that the ratio of the upper width W7 and the lower width W8 satisfies 1:0.8 to 1:1.2.

Meanwhile, the forming of the outer circuit pattern 226 on the substrate laminate 230 and the forming of the resist pattern 228 may be further performed. Therefore, the outer circuit pattern 226 electrically connected to the inner circuit pattern 214 by the conductive via 230 and the resist pattern 228 selectively exposing the outer circuit pattern 226 may be formed on the substrate laminate 230.

The method for manufacturing a circuit board according to the exemplary embodiment of the present invention manufactures the substrate laminate 230 by forming the insulating layer 220 including the inner layer 222 and the outer layer 224 on the base substrate 210 and may form on the substrate laminate 230 and the via hole 227 having approximately the same outer side width W5 and inner side width W6′ while penetrating through the inner layer 222 and the outer layer 224, and then, form the conductive via 140 in the via hole 227. Therefore, the method for manufacturing a circuit board according to the exemplary embodiment of the present invention have the conductive via of which the upper and lower widths are approximately the same to reduce the electrical resistance thereof, such that the circuit board having the structure with the improved electrical characteristics can be manufactured.

The method for manufacturing a circuit board according to another exemplary embodiment of the present invention manufactures the substrate laminate 230 by forming the insulating layer 220 on the base substrate 210 and may form on the substrate laminate 230 and the conductive via 240 having approximately the same upper width W7 and lower width W8 while penetrating through the inner layer 222 and the outer layer 224. In this case, the conductive via 240 can reduce the occupying area of the substrate laminate 230, as compared with the conductive via of which the upper and lower widths are different under the condition of having the same electrical resistance. Therefore, the method for manufacturing a circuit board according to the exemplary embodiment of the present invention may form the conductive via of which the upper and lower widths are approximately the same to relatively reduce the occupying area, such that a thin and fine-pitch circuit board can be manufactured.

In addition, the method for manufacturing a circuit board according to another exemplary embodiment of the present invention may form the via hole 227 having the same shape where the outer side width W5 and the inner side width W6′ are approximately the same and then, form the conductive via 240 in the via hole 227 by the plating process. Therefore, the method for manufacturing the circuit board according to the exemplary embodiment of the present invention can form the via holes of which the outer side width and the inner side width are the same to facilitate the permeation of the plating solution as compared with the via holes having a narrow width toward the base substrate, thereby making it possible to improve the efficiency of forming the conductive vias.

As set forth above, the via structure according to the exemplary embodiment of the present invention includes the conductive vias of which the upper and lower widths are approximately the same to provide the conductive vias having the structure where the electrical resistance of the conductive vias is reduced, thereby making it possible to improve the electrical characteristics of the circuit board when the circuit board is manufactured by using the via structure.

Further, the via structure according to the exemplary embodiment of the present invention includes the conductive vias of which the upper and lower widths are approximately the same to relatively reduce the occupying area thereof, thereby making it possible to implement thinness and fine-pitch of the circuit board when the circuit board is manufactured by using the via structure.

Further, the method for forming a via structure according to the exemplary embodiment of the present invention forms the conductive vias of which the upper and lower widths are approximately the same, thereby making it possible to form the conductive vias having small electrical resistance.

Further, the method for forming the via structure according to the exemplary embodiment of the present invention forms the conductive vias of which the upper and lower widths are approximately the same, thereby making it possible to relatively reduce the occupying area of the conductive vias when manufacturing the circuit board using the conductive vias.

Further, the circuit board according to the exemplary embodiment of the present invention includes the conductive vias of which the upper and lower widths are approximately the same to reduce the electrical resistance thereof, such that the electrical characteristics thereof can be improved.

Further, the circuit board according to the exemplary embodiment of the present invention includes the conductive vias of which the upper and lower widths are approximately the same to relatively reduce the occupying area thereof, thereby making it possible to implement the structure where thinness and fine-pitch of the circuit board can be achieved.

The method for manufacturing the circuit board according to the exemplary embodiment of the present invention forms the conductive vias of which the upper and lower widths are approximately the same to reduce the electrical resistance of the conductive vias, thereby making it possible to manufacture the circuit board with the improved electrical characteristics.

Further, the method for manufacturing a circuit board according to the exemplary embodiment of the present invention includes the conductive vias of which the upper and lower widths are approximately the same to relatively reduce the occupying area of the conductive vias, thereby making it possible to manufacture the circuit board having the structure where thinness and fine-pitch can be achieved.

Further, the method for manufacturing the circuit board according to the exemplary embodiment of the present invention can form the via hole of which the outer side width and the inner side width are the same to facilitate the permeation of the plating solution as compared with the via hole having a narrow width toward the base substrate, thereby making it possible to improve the efficiency of forming the conductive vias.

The above detailed description exemplifies the present invention. Further, the above contents just illustrate and describe preferred embodiments of the present invention and the present invention can be used under various combinations, changes, and environments. That is, it will be appreciated by those skilled in the art that substitutions, modifications and changes may be made in these embodiments without departing from the principles and spirit of the general inventive concept, the scope of which is defined in the appended claims and their equivalents. Although the exemplary embodiments of the present invention have been disclosed for illustrative purposes, those skilled in the art will appreciate that various modifications, additions and substitutions are possible, without departing from the scope and spirit of the invention as disclosed in the accompanying claims. Therefore, the detailed description of the present invention does not intend to limit the present invention to the disclosed embodiments. Further, it should be appreciated that the appended claims include even another embodiment.

1. A circuit board, comprising:
a base substrate having inner circuit patterns;
an insulating layer covering the base substrate;
a via hole penetrating through the base substrate and the insulating layer so that the inner circuit pattern is exposed; and
a conductive via included in the via hole,
wherein the base substrate includes a core layer made of a resin material, and
the core layer includes a polymer resin layer made of a material having a faster etching rate using an alkaline chemical liquid, as compared with the insulating layer.

2. The circuit board according to claim 1, wherein the core layer and the insulating layer are made of a polymer resin composition having a resin and a filler, and
the core layer has a relatively higher content of the filler for the resin, as compared with the insulating layer.

3. The circuit board according to claim 2, wherein the core layer is formed so that the content ratio of the filler for the resin is 0.8 to 1.5.

4. The circuit board according to claim 1, wherein the core layer and the insulating layer are made of a complex resin composition having an epoxy resin and a bismaleimide triazine resin, and
the core layer has a higher content of the epoxy resin, as compared with the insulating layer.

5. The circuit board according to claim 1, wherein the core layer is made of the epoxy resin, and
the insulating layer is made of the bismaleimide triazine resin.

6. The circuit board according to claim 1, wherein the conductive via is formed so that a ratio of a width at the insulating layer and a width at the base substrate satisfies 1:0.8 to 1:1.2.

7. The circuit board according to claim 1, wherein the inner circuit patterns are formed on both surfaces of the base substrate,
the circuit board further includes an outer circuit pattern covering the insulating layer, and
one end of the conductive via is connected to the inner circuit pattern formed on one surface of the base substrate and the other end thereof is connected to the outer circuit pattern formed on the insulating layer covering the other surface of the base substrate.

8. The circuit board according to claim 1, wherein the base substrate and the insulating layer form a substrate laminate,
the via hole is formed by performing a laser machining process on the substrate laminate, and
the conductive via is a plating layer filling the via hole.

9. A method for manufacturing a circuit board, comprising:
preparing a base substrate having an inner circuit pattern;
manufacturing a substrate laminate by forming an insulating layer covering the base substrate;
forming a via hole exposing the inner circuit pattern on the substrate laminate; and
forming a conductive via in the via hole,
wherein the forming the insulating layer includes forming a polymer resin layer made of a resin material having a slow etching rate using an alkaline chemical liquid on the base substrate, as compared with the base substrate.

10. The method for manufacturing a circuit board according to claim 9, wherein the forming the via hole includes:
forming a preliminary via hole having a narrower width at the base substrate than a width at the insulating layer by performing a laser machining process on the substrate laminate; and
expanding the width at the base substrate of the preliminary via hole so that a ratio of the width at the insulating layer and the width at the base substrate satisfies 1:0.8 to 1:1.2.

11. The method for manufacturing a circuit board according to claim 10, wherein the expanding the width at the base substrate of the preliminary via hole includes performing a desmear process having a faster etching rate for the base substrate than for the insulating layer on the substrate laminate.

12. The method for manufacturing a circuit board according to claim 10, wherein the expanding the width at the base substrate of the preliminary via hole includes supplying an alkaline chemical liquid having etch selectivity for the base substrate to the substrate laminate.

13. The method for manufacturing a circuit board according to claim 9, wherein the preparing the base substrate includes preparing a copper clad laminate having a core layer made of a resin material, and
the forming the insulating layer includes forming a polymer resin layer made of a slower etching rate by an alkaline chemical liquid on the copper clad laminate, as compared with the core layer.

14. The method for manufacturing a circuit board according to claim 9, wherein the forming the insulating layer includes laminating a polymer sheet having a lower content of a filler than that of a resin, as compared with the core layer on the copper clad laminate.

15. The method for manufacturing a circuit board according to claim 14, wherein the core layer is formed so that the content ratio of the filler for the resin is 0.8 to 1.5.

16. The method for manufacturing a circuit board according to claim 13, wherein the forming the polymer resin layer includes laminating a polymer sheet having a relatively higher content of a bismaleimide triazine resin, as compared with the copper clad laminate.

17. A circuit board, comprising:
a base substrate having inner circuit patterns;
an insulating layer covering the base substrate and having a multilayer structure;
a via hole penetrating through the insulating layer so that the inner circuit pattern is exposed; and
a conductive via provided in the via hole,
wherein the multilayer structure is made of a resin material having a low decomposition rate using an alkaline chemical liquid toward the base substrate.

18. The circuit board according to claim 17, wherein the multilayer structure includes:
an inner layer covering the base substrate; and
an outer layer covering the inner layer,
the inner layer including a prepreg layer made of a resin material, and
the outer layer including a prepreg layer made of a resin material having a low decomposition rate using an alkaline chemical liquid, as compared with the inner layer.

19. The circuit board according to claim 17, wherein the multilayer structure is made of a polymer resin composition including a resin and a filler, and the multilayer structure includes:
an inner layer covering the base substrate; and
an outer layer covering the inner layer,
the inner layer having a higher content of the filler for the resin, as compared with the outer layer.

20. The circuit board according to claim 19, wherein the inner layer is formed so that the content ratio of the filler for the resin is 0.8 to 1.5.

21. The circuit board according to claim 17, wherein the multilayer structure includes:
an inner layer covering the base substrate; and
an outer layer covering the inner layer,
the conductive via being formed so that a ratio of the width at the outer layer and the width of the inner layer satisfies 1:0.8 to 1:1.2.

22. The circuit board according to claim 17, further comprising an outer circuit pattern covering the insulating layer,
wherein one end of the conductive via is connected to the inner circuit pattern and the other end thereof is connected to the outer circuit pattern.

23. The circuit board according to claim 17, wherein the base substrate and the insulating layer form a substrate laminate,
the via hole is formed by performing a laser machining process on the substrate laminate, and
the conductive via is a plating layer filling the via hole.

24. A method for manufacturing a circuit board, comprising:
preparing a base substrate having inner circuit patterns;
manufacturing a substrate laminate by forming an insulating layer on the base substrate;
forming a via hole exposing the inner circuit pattern on the substrate laminate; and
forming a conductive via having a shape corresponding to the via hole in the via hole,
wherein the forming the insulating layer includes:
forming an inner layer adjacent to the base substrate; and
forming an outer layer made of a resin material having a low decomposition rate using an alkaline chemical liquid on the inner layer, as compared with the inner layer.

25. The method for manufacturing a circuit board according to claim 24, wherein the forming the via hole includes:
forming a preliminary via hole having a narrower width at the inner layer than a width at the outer layer by performing a laser machining process on the substrate laminate; and
expanding the width at the inner layer of the preliminary via hole so that a ratio of the width at the outer layer and the width at the inner layer satisfies 1:0.8 to 1:1.2.

26. The method for manufacturing a circuit board according to claim 24, wherein the expanding the width at the inner layer of the preliminary via hole includes performing a desmear process having a faster etching rate for the inner layer than for the outer layer on the substrate laminate.

27. The method for manufacturing a circuit board according to claim 24, wherein the expanding the width at the inner layer of the preliminary via hole includes supplying an alkaline chemical liquid having etch selectivity for the inner layer to the substrate laminate.

28. The method for manufacturing a circuit board according to claim 24, wherein the forming the insulating layer includes laminating a polymer sheet including the inner layer and the outer layer on the base substrate.

29. The method for manufacturing a circuit board according to claim 24, wherein the forming the outer layer includes laminating a polymer sheet having a lower content of a filler for a resin, as compared to the inner layer on the inner layer.

30. The method for manufacturing a circuit board according to claim 24, wherein the inner layer is formed so that the content ratio of the filler for the resin is 0.8 to 1.5.

31. The method for manufacturing a circuit board according to claim 24, wherein the forming the outer layer includes laminating a polymer sheet having a relatively higher content of a bismaleimide triazine resin, as compared with the copper clad laminate.

32. A via structure, comprising:
a substrate laminate having a multilayer structure and a via hole penetrating through the multilayer structure;
a first circuit pattern formed on one surface of the substrate laminate;
a second circuit pattern formed on the other surface of the substrate laminate; and
a conductive via formed in the via hole and having one end connected to the first circuit pattern and the other end connected to the second circuit pattern,
wherein the multilayer structure includes resin layers having different etching rates using an alkaline solution.

33. The via structure according to claim 32, wherein the resin layers are made of a polymer resin composition having a resin and a filler,
each of the resin layers is provided to have a different content of the filler for the resin, and
the resin layers are disposed in sequence where the content of the filler for the resin is high toward a thickness direction of an insulator.

34. The via structure according to claim 32, wherein the resin layer having a relatively faster etching rate for the alkaline solution among the resin layers has a higher content of the epoxy resin than a bismaleimide triazine resin, as compared with the resin layer having a slower etching rate using the alkaline solution.

35. The via structure according to claim 32, wherein the conductive via is formed so that a ratio of the width at the resin layer having a relatively faster etching rate using the alkaline solution among the resin layers and the width at the resin layer having a relatively slow etching rate using the alkaline solution satisfies 1:0.8 to 1:1.2.

36. A method for manufacturing a via structure, comprising:
manufacturing an insulator having a multilayer structure;
forming a via hole penetrating through the multilayer structure;
forming a first circuit pattern on one surface of the insulator;
forming a second circuit pattern on the other surface of the insulator;
forming a conductive via having one end connected to the first circuit pattern and the other end connected to the second circuit pattern in the via hole; and
forming resin layers having different etching rates for an alkaline solution forming the insulator.

37. The method for manufacturing a via structure according to claim 36, wherein each of the resin layers is made of a polymer resin composition having a resin and a filler, and
the forming the resin layers includes stacking the resin layers so that the content of the filler for the resin is relatively high toward the thickness direction of the insulator.

38. The method for manufacturing a via structure according to claim 36, wherein the forming the resin layers includes stacking the resin layers so that the content of an epoxy resin is relatively higher than that of a bismaleimide triazine resin toward the thickness direction of the insulator.

39. The method for manufacturing a via structure according to claim 36, wherein the forming the via hole includes:
forming a preliminary via hole having a narrower width at the other side of the insulator than that at one side of the insulator by irradiating a laser beam to one side of the insulator; and
performing a desmear process on the insulator in order to expand a width at the other side of the insulator of the preliminary via hole.

40. The method for manufacturing a via structure according to claim 39, wherein the performing the desmear process includes expanding the width at the resin layer having a relatively faster etching rate using the alkaline solution so that a ratio of the width at the resin layer at a relatively faster etching rate using the alkaline solution among the resin layers and the width at the resin layer at a relatively slower etching rate using the alkaline solution satisfies 1:0.8 to 1:1.2.
